(19) United States
(12) Patent Application Publication
(10) Pub. No.: US 2012/0120595 A1
(43) Pub. Date: May 17, 2012

(54) COMPUTER SYSTEM WITH AIRFLOW GUIDING DUCT

(75) Inventors: HONG-ZHI SUN, Shenzhen City (CN); CHEN CHEN, Shenzhen City (CN); YANG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO.,LTD., Shenzhen City (CN)

(21) Appl. No.: 13/170,957

(22) Filed: Jun. 28, 2011

(30) Foreign Application Priority Data
Nov. 16, 2010 (CN) 201010546402.3

(51) Int. Cl. H05K 7/20

(52) U.S. Cl. 361/679.47

(57) ABSTRACT

A computer system includes a computer case and a heat dissipating device. The heat dissipating device includes a heat sink, a fan and an airflow guiding duct. The fan is attached to the heat sink, and the airflow guiding duct covers on the fan. The airflow guiding duct includes a bottom panel, two side panels and a blocking panel. Each side panel includes a first panel and a second panel connected to the first panel. The blocking panel is slanted and connected to the bottom panel and the second panel of each side panel, the blocking panel is adapted to allow the air to pass through the airflow guiding duct, and an inward direction of the airflows generated by the fan is substantially perpendicular or oblique to an outward direction of the airflow.

### BACKGROUND

1. Technical Field

The present disclosure relates to computer systems, and more particularly to a computer system with an airflow guiding duct.

2. Description of Related Art

Heat dissipating devices perform the critical function of removing heat from an electronic device. The heat dissipating device often includes one or more fans received in a bracket. Airflow from outside of the electronic device is directed inside and then back out of the electronic device by the fan, for dissipating heat generated in the electronic device. However, if the air flows in a disorderly manner in the electronic device, it will decrease heat dissipating efficiency of the electronic device.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of an exemplary embodiment of a computer system.

FIG. 2 is an isometric view of an airflow guiding duct of FIG. 1.

FIG. 3 is an assembled view of FIG. 1.

FIG. 4 is similar to FIG. 3, but viewed from another aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

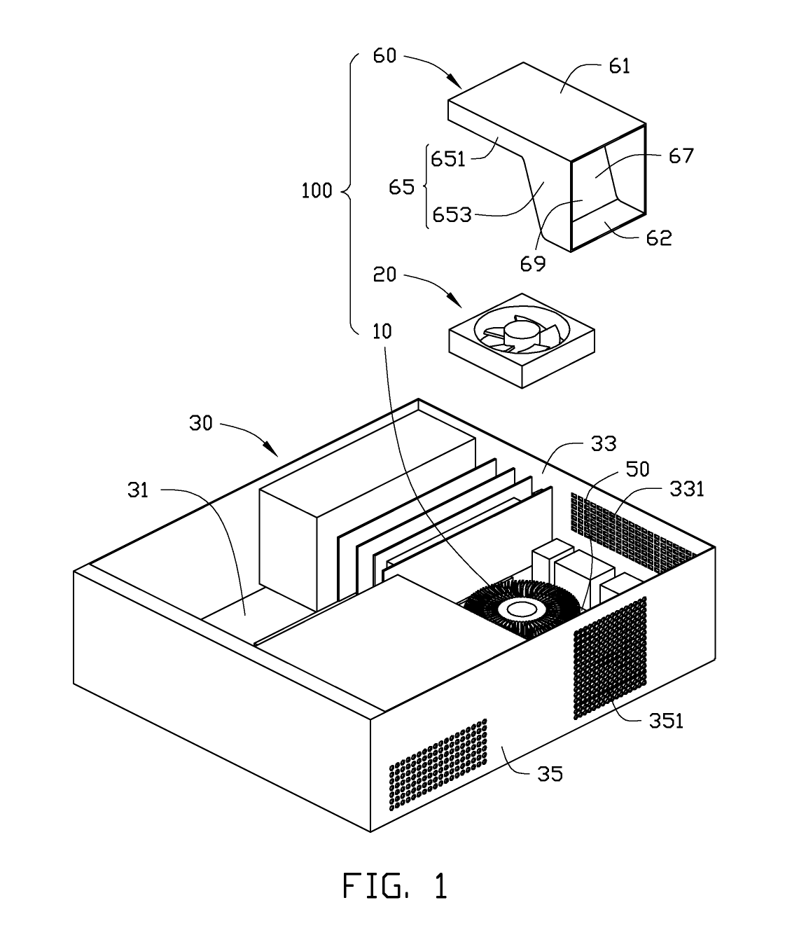

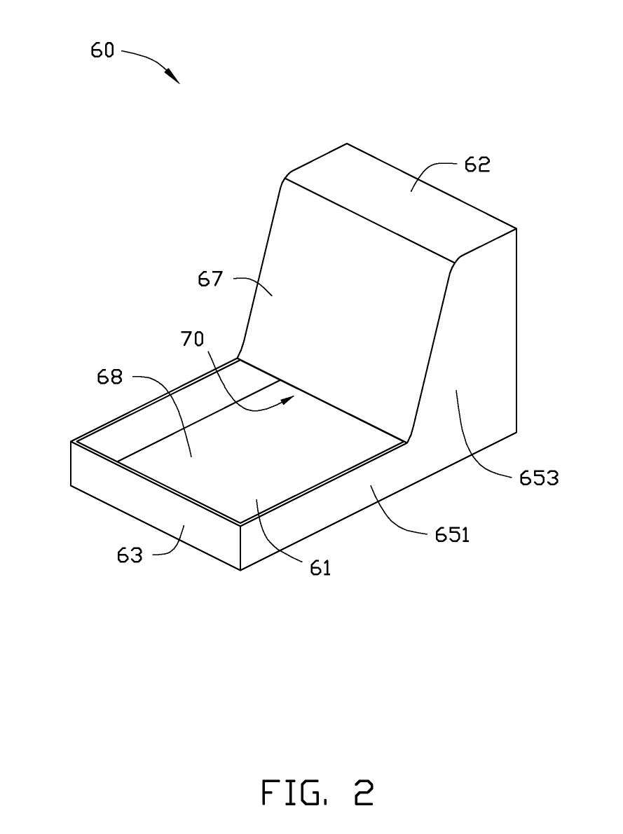

Referring to FIGS. 1 and 2, an electronic device in accordance with an exemplary embodiment includes a computer case 30 and a heat dissipating apparatus 100 received in the computer case 30.

The computer case 30 includes a bottom plate 31, a first side plate 33 and a second side plate 35. The first side plate 33 and the second side plate 35 are integrally formed on the bottom plate 31 or otherwise coupled with the bottom plate 31. The computer case 30 can have various configurations, such as a different wall or base configurations so long as the bottom plate 31 is adapted to couple with a cover (not shown) to create a housing. In one exemplary embodiment, the first side plate 33 is substantially perpendicular to the bottom plate 31 and the second side plate 35.

A motherboard 50 is located on the bottom plate 31 and includes a heat generating chip (not shown). In one exemplary embodiment, the chip can be a CPU, and the CPU can generate heat, which can increase the temperature in the computer case 30. A plurality of first ventilation holes 331 is defined in the first side plate 33, and a plurality of second ventilation holes 351 is defined in the second side plate 35. Air from outside of the computer case 30, may flow into the computer case 30 via the plurality of first ventilation holes 331, and may flow out of the computer case 30 via the plurality of second ventilation holes 351.

The heat dissipating device 100 includes a heat sink 10, a fan 20 and an airflow guiding duct 60. The heat sink 10 is attached to the chip, and the fan 20 is attached to the heat sink 10.

The airflow guiding duct 60 includes a top panel 61, a bottom panel 62, a front panel 63, two side panels 65, and a blocking panel 67. In one exemplary embodiment, the top panel 61 is substantially parallel to the bottom panel 62, and the blocking panel 67 is at an obtuse angle to the bottom panel 62. Each side panel 65 includes a first panel 651 and a second panel 653 connected to the first panel 651. The front panel 63, the two first panels 651 cooperatively define an air inlet 68. The two second panels 653, the bottom panel 62 and the blocking panel 67 cooperatively define an air outlet 69. The blocking panel 67 is connected to the bottom panel 62 and the two second panels 653. A channel 70 is defined to communicate the air inlet 68 with the air outlet 69. In one exemplary embodiment, the first panel 651 is substantially perpendicular to the top panel 61 and at an obtuse angle to the second panel 653, and a height of the first panel 651 is less than the height of the second panel 653.

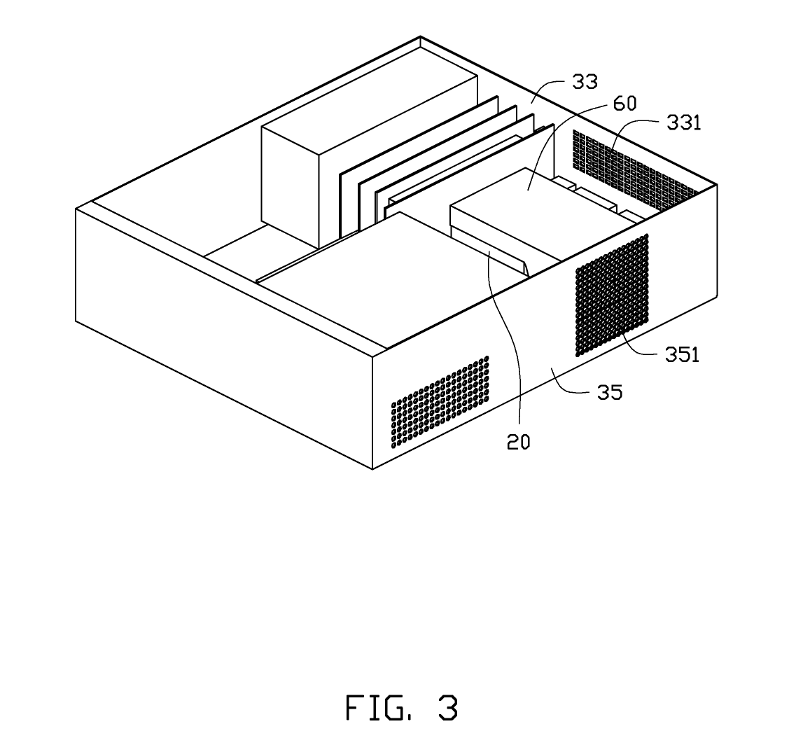

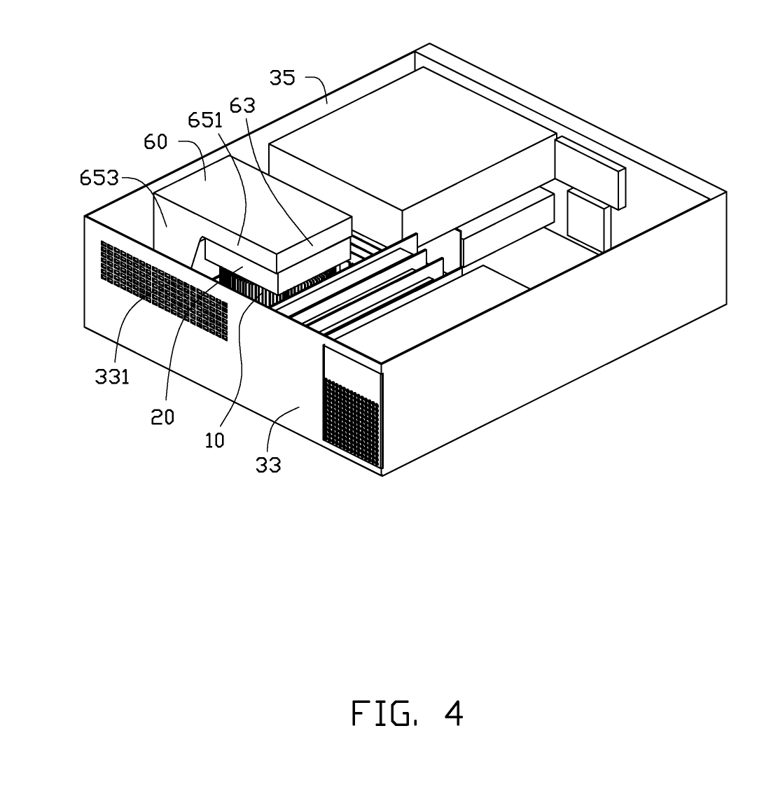

Referring to FIGS. 3-4, in assembly, the heat sink 10 is secured to the chip, and the fan 20 is secured to the heat sink using a common fastener, for locating the heat sink 10 between the chip and the fan 20.

The airflow guiding duct 60 is placed in the computer case 30. The fan 20 is received by and fits in the air inlet 68, and the outlet 69 is directed towards to the plurality of second ventilation holes 351 and located at a side of the heat sink 10 and the fan 20. The bottom panel 62 is secured to the bottom plate 31 by fasteners. The front panel 63 and the two first panels 651 are secured to the fan 20 by screws or other common fasteners. Therefore, the heat sink 10 and the fan 20 are together located on the same side of the blocking panel 67. In one exemplary embodiment, the second panel 653 abuts the second side plate 35 and substantially perpendicular to the second side plate 35, and the top panel 61 is substantially parallel to the bottom plate 31.

In use, the heat generated by the chip is transferred to the heat sink 10 and the fan 20. The air flows into the computer case 30 via the plurality of first ventilation holes 331, flowing through the second fan 10 and into the air inlet 68. Then, the air flows into the air outlet 69 via the channels 70, and out of the computer case 30 via the plurality of second ventilation holes 351. Therefore, heat generated from the chip can be effectively removed. In one exemplary embodiment, an inward direction of the airflows generated by the fan 20 is substantially perpendicular or oblique to an outward direction of the airflow.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A computer system, comprising:
a computer case; and
a heat dissipating device, located in the computer case, comprising a heat sink, a fan and an airflow guiding duct; the fan attached to the heat sink, and the airflow guiding duct covering the fan; the airflow guiding duct comprising a bottom panel, two side panels and a blocking panel; each of the two side panels comprising a first panel and a second panel connected to the first panel;
wherein the blocking panel is slanted relative to and connected to the bottom panel and the second panel of each side panel, the blocking panel is adapted to allow the air to pass through the airflow guiding duct, and an inward direction of the airflow generated by the fan is at least substantially oblique to an outward direction of the airflow.

2. The computer system of claim 1, wherein the airflow generated by the fan is at least substantially perpendicular to an outward direction of the airflow.

3. The computer system of claim 1, wherein a height of the first panel is less than the height of the second panel.

4. The computer system of claim 1, wherein the blocking panel is at an obtuse angle to the bottom panel.

5. The computer system of claim 1, wherein the second panel is at an obtuse angle to the first panel.

6. The computer system of claim 1, wherein the fan and the heat sink are located on the same side of the blocking panel.

7. The computer system of claim 1, wherein the airflow guiding duct defines an air inlet, an air outlet and a channel communicating the air inlet and the air outlet, and the fan is received in the air inlet.

8. The computer system of claim 7, wherein the airflow guiding duct further comprises a front panel, and the front panel and the first panel of each side panel together define the air inlet.

9. The computer system of claim 7, wherein the blocking panel, the bottom panel and the second panel of each side panel together define the air outlet.

10. The computer system of claim 1, wherein the computer case comprises a first side plate and a second side plate substantially perpendicular to the first side plate, a plurality of first ventilation holes is defined in the first side plate, and a plurality of second ventilation holes is defined in the second side plate.

11. The computer system of claim 10, wherein the second panel abuts the second side plate and is substantially perpendicular to the second side plate.

12. A computer system, comprising:
a computer case comprising a bottom plate and a side plate substantially perpendicular to the bottom plate; and
a heat dissipating device, received in the computer case, comprising an airflow guiding duct, a heat sink and a fan attached to the heat sink; the air guiding duct comprising a bottom panel, a top panel substantially parallel to the bottom panel, two side panels substantially perpendicular to the bottom panel, a front panel substantially perpendicular to the bottom panel, and a blocking panel slanted relative to and connected to the bottom plate; each side panel comprising a first panel and a second panel connected to the first panel;
wherein a height of the first panel is less than the height of the second panel, the bottom panel is attached to the bottom plate; the top panel, the front panel and the first panel of each side panel together define an air inlet, and the fan is received in the air inlet.

13. The computer system of claim 12, wherein an inward direction of the airflows generated by the fan is substantially perpendicular or oblique to an outward direction of the airflow.

14. The computer system of claim 12, wherein the blocking panel is at an obtuse angle to the bottom panel.

15. The computer system of claim 12, wherein the second panel is at an obtuse angle to the first panel.

16. The computer system of claim 12, wherein the fan and the heat sink are together located on the same side of the blocking panel.

17. The computer system of claim 16, wherein the airflow guiding duct defines an air outlet communicating with the air inlet, the blocking panel, the bottom panel and the second panel of each side panel together define the air outlet.

18. The computer system of claim 12, wherein the computer case comprises a first side plate and a second side plate substantially perpendicular to the first side plate, a plurality of first ventilation holes is defined in the first side plate, and a plurality of second ventilation holes is defined in the second side plate.

19. The computer system of claim 18, wherein the second panel abuts the second side plate and substantially perpendicular to the second side plate.
